(19) United States
(12) Patent Application Publication
(10) Pub. No.: US 2009/0020877 A1
(43) Pub. Date: Jan. 22, 2009

(54) TRANSMISSION LINE STRUCTURE AND SIGNAL TRANSMISSION STRUCTURE

(75) Inventor: Sheng-Yuan Lee, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/860,771

(22) Filed: Sep. 25, 2007

(30) Foreign Application Priority Data
Jul. 16, 2007 (TW) 96125833

(51) Int. Cl. H01L 23/48

(52) U.S. Cl. 257/773; 257/E23.01

(57) ABSTRACT

A transmission line structure includes a routing trace, a doped region and a first guard trace. The routing trace is disposed over a substrate. The doped region is disposed in the substrate and the projection of at least the partial routing trace falls within the doped region. The first guard trace is located over the substrate and disposed with a space from the routing trace, wherein the first guard trace is grounded and electrically coupled with the doped region. In addition, the conductivity of the first guard trace is higher than the conductivity of the doped region.

### CROSS-REFERENCE TO RELATED APPLICATION

This application claims the priority benefit of Taiwan application serial no. 96125833, filed on Jul. 16, 2007. All disclosure of the Taiwan application is incorporated herein by reference.

### BACKGROUND OF THE INVENTION

1. Field of the Invention

The present invention generally relates to a transmission line structure and a signal transmission structure, and more particularly, to a transmission line structure and a signal transmission structure having better signal transmission quality.

2. Description of Related Art

In the semiconductor industry, it has become the tendency of the industry to develop integrated circuit (IC) chips with high integrity and high processing speed. Along with the steady advancements of IC chip efficiency, the transmission frequency of electronic signals in a chip is gradually increased. When the frequency of an electronic signal is increased to a high-frequency status however, for example, beyond a gigahertz (GHz, i.e. one thousand million hertz), the internal signals of a chip would be easily and seriously interfered by noise, so that transmission distortion caused by the noise gets more significantly, wherein crosstalk is considered as one of the most common noise interferences. In fact, crosstalk phenomenon mainly comes from a coupling between two adjacent conductors and the thereby resulted parasitic inductance and parasitic capacitance, and the crosstalk gets more seriously with increasing trace density.

The electronic signals between the internal devices of a chip are usually communicated by a signal transmission structure. A signal transmission structure for interconnecting two devices or two endpoints needs to be designed to keep the characteristic impedance thereof unchanged during communicating of electronic signals. In particular, for the case of transmitting signals in high speed or high frequency, a proper impedance matching design between two devices or two endpoints is especially necessary for lowering a reflection caused by unmatched impedance and relatively increasing return loss during transmitting signals so as to avoid any negative influence on signal transmission quality.

In general speaking, a coupling between metal traces and a silicon substrate in a chip and the parasitic inductance or parasitic capacitance caused by the coupling would result in an energy loss. The low conductivity nature of the silicon substrate make the lost energy dispersed throughout the silicon substrate, and moreover, the energy dispersed in the silicon substrate usually couples with other devices or traces to produce noise interference.

In order to reduce the noise interference occurred in a silicon substrate, a conventional transmission line structure usually takes a shielding structure design between the silicon substrate and the metal traces so as to isolate any possible coupling between the silicon substrate and the metal traces and reduce noise interference. Regardless of the fact that a shielding structure is able to reduce noise interference caused by a coupling from the metal traces to the silicon substrate, however, the shielding structure is unable to provide a satisfied ground path to prevent the noise from being diffused away.

### SUMMARY OF THE INVENTION

Accordingly, the present invention is directed to a transmission line structure and a signal transmission structure capable of reducing crosstalk phenomenon, introducing noise out through a grounded guard trace and lowering noise interference.

To achieve the above-mentioned or other objectives, the present invention provides a transmission line structure, which includes a routing trace, a doped region and a first guard trace. The routing trace is disposed over a substrate. The doped region is disposed in the substrate and the projection of at least the partial routing trace falls within the doped region. The first guard trace is located over the substrate and spaced from the routing trace. Besides, the first guard trace is grounded and electrically coupled with the doped region. The conductivity of the first guard trace is higher than that of the doped region.

The present invention also provides a signal transmission structure, which includes a plurality of components and a transmission line structure. The components are disposed over a substrate and the transmission line structure is located between two adjacent components. The transmission line structure includes a routing trace, a doped region and a first guard trace. The routing trace is disposed over the substrate and electrically coupled with two adjacent components. The doped region is disposed in the substrate and the projection of at least the partial routing trace falls within the doped region. The first guard trace is located over the substrate and spaced from the routing trace. Besides, the first guard trace is grounded and electrically coupled with the doped region. The conductivity of the first guard trace is higher than that of the doped region.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view diagram of a transmission line structure according to an embodiment of the present invention.

FIG. 1B is a cross-sectioned diagram along line I-I′ in FIG. 1A.

FIG. 1C is a cross-sectioned diagram along line I-I′ in FIG. 1A according to another embodiment of the present invention.

FIG. 1D is a cross-sectioned diagram along line I-I′ in FIG. 1A according to yet another embodiment of the present invention.

FIG. 1E is a top view diagram of a transmission line structure according to yet another embodiment of the present invention.

FIG. 2A is a top view diagram of a transmission line structure according to other embodiments of the present invention.

FIG. 2B is a cross-sectioned diagram along line II-II′ in FIG. 2A.

FIG. 2C is a cross-sectioned diagram along line II-II′ in FIG. 2A according to another embodiment of the present invention.

FIG. 2D is a cross-sectioned diagram of a transmission line structure according to yet another embodiment of the present invention.

FIG. 3 is a top view diagram of a signal transmission structure according to an embodiments of the present invention.

FIG. 4 is a graph showing different return loss curves vs. frequencies of clock signal respectively corresponding to the transmission line structure 100 provided by an embodiment of the present invention, and two conventional transmission line structures 300 and 400.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

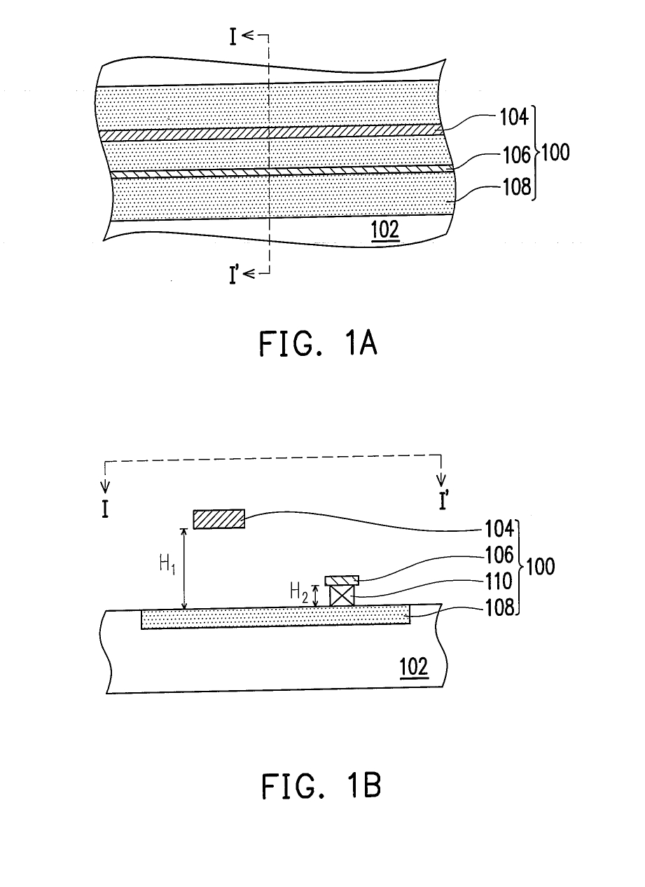

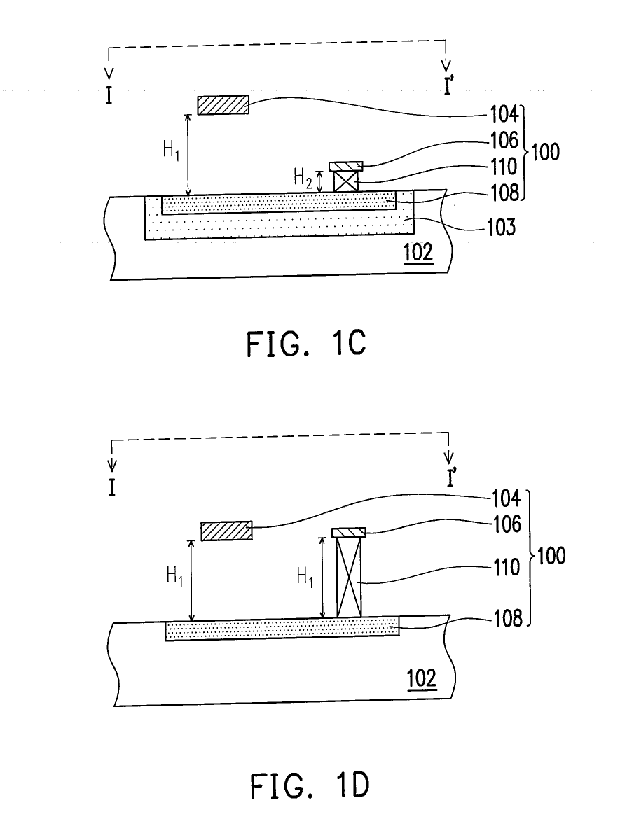

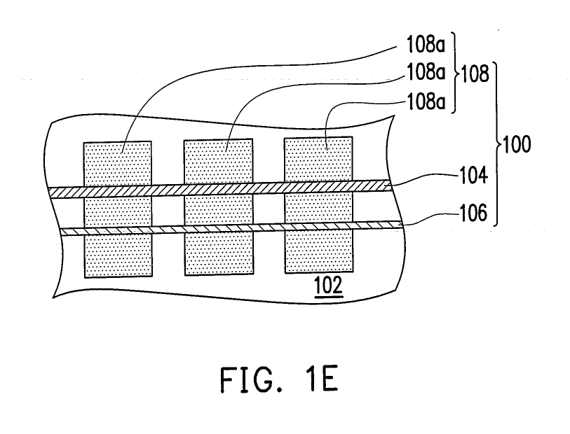

FIG. 1A is a top view diagram of a transmission line structure according to an embodiment of the present invention, FIG. 1B is a cross-sectioned diagram along line I-I′ in FIG. 1A and FIG. 1C is a cross-sectioned diagram along line I-I′ in FIG. 1A according to another embodiment of the present invention.

Referring to FIGS. 1A and 1B, a transmission line structure 100 includes a routing trace 104, a guard trace 106 and a doped region 108. The routing trace 104 and the guard trace 106 are disposed over a substrate 102 and spaced from each other. The doped region 108 is disposed in the substrate 102, for example, located at the most upper portion of the substrate 102. The transmission line structure 100 may be implemented by a semiconductor process, wherein the substrate 102 is, for example, P-type silicon substrate. The material of the routing trace 104 may be metal, for example, copper or copper aluminum alloy. The material of the guard trace 106 may be conductive material, for example, metal or poly silicon. The doped region 108 may be, for example, a P-type heavily doped region.

Referring to FIG. 1C of another embodiment, the transmission line structure 102 further includes a well region 103 disposed, for example, in the substrate 102, while the doped region 108 is disposed in the well region 103. When the substrate 102 is P-type silicon substrate, the well region 103 is, for example, an N-type well region. The doped region 108 is corresponding to the well region 103 and may be an N-type heavily doped region located at the most upper portion of the substrate 102. Certainly, the conductivity type of the substrate 102 and the conductivity type of the doped region 108 may also take other combinations, which anyone skilled in the art is able to modify according to a practical process.

Referring to FIGS. 1A, 1B and 1C, the routing trace 104 is located, for example, at a height H₁ from the surface of the substrate 102 and for providing the internal electronic signals of a chip with a transmission path.

The guard trace 106 is extended, for example, along a direction parallel to the extension direction of the routing trace 104 and disposed at a side of the routing trace 104. The length of the guard trace 106 is, for example, equal to the length of the routing trace 104. In the embodiment, the guard trace 106 is located at a height H₂ from the surface of the substrate 102, and the height H₁ is greater than the height H₂, i.e., the guard trace 106 and the routing trace 104 are respectively at different elevations.

FIG. 1D is a cross-sectioned diagram along line I-I′ in FIG. 1A according to yet another embodiment of the present invention. In the FIG. 1D, the same components as FIG. 1B are marked by the same notations, which are omitted to describe herein.

Referring to FIG. 1D, in yet another embodiment, the guard trace 106 is, for example, located at a height H₁ from the surface of the substrate 102. That is to say, the guard trace 106 may also be located at a side of the routing trace 104 and take the same elevation as the routing trace 104.

Referring to FIGS. 1A-1D again, the doped region 108, for example, forms a part of the upper surface of the substrate 102, and the projection of at least the partial routing trace 104 falls within the doped region 108 so as to make the doped region 108 served as a shielding structure to isolate the routing trace 104 from the substrate 102. That is to say, the projection of the routing trace 104 may either partially fall within the doped region 108, or completely fall within the doped region 108 (as shown by FIG. 1A). In more detail, as long as the doped region 108 shield a part of the coupling between the routing trace 104 and the substrate 102, the noise injected from the routing trace 104 into the substrate 102 is able to be reduced so as to advance the signal transmission quality. As shown by FIG. 1A, when the projection of the routing trace 104 completely falls within the doped region 108, a better shielding effect contributed by the doped region 108 between the routing trace 104 and the substrate 102 is expected.

In addition, the doped region 108 may be coupled with the grounded guard trace 106 by design, wherein, for example, a via plug 110 is disposed between the doped region 108 and the guard trace 106 so as to make the doped region 108 electrically connected to the guard trace 106. Due to the guard trace 106 is grounded, the doped region 108 obtains a good ground path through the guard trace 106, so that the noise gathered in the doped region 108 is able to be discharged through the guard trace 106 which effectively reduce the noise interference of the transmission line structure 100.

Note that the guard trace 106 disposed at a side of the routing trace 104 is able to provide a good signal return path during signal transmission, which is helpful to lower crosstalk; i.e., the guard trace 106 has a function of protecting signals to avoid any unexpected noise interference.

FIG. 1E is a top view diagram of a transmission line structure according to yet another embodiment of the present invention, wherein the components having the same notations as FIG. 1A are omitted to describe.

Referring to FIG. 1E, the doped region 108 may also be formed by over two doped areas 108a. In the embodiment, the doped region 108 is formed by three doped areas 108a, and there is, for example, a space between two adjacent doped areas 108a. When the doped region 108 includes a plurality of doped areas 108a, the way for the doped region 108 to be grounded is implemented by respectively grounding each of the doped areas 108a. Thus, each of the doped areas 108a is electrically connected to the guard trace 106 through, for example, a via plug 110, so that every doped area 108a is able to be grounded through the guard trace 106. Although the embodiment exemplarily takes a doped region 108 composed of three doped areas 108a, but the present invention does not limit thereto. In other embodiments, the doped region 108 may include over one doped area 108a, and the grounding way of the doped region 108 is also not limited to the above-embodiment; the key point is to respectively make each doped area 108a coupled with the guard trace 106. Besides, once the doped region 108 is able to shield a part of the coupling between the routing trace 104 and the substrate 102, the goal to reduce the noise injected from the routing trace 104 into the substrate 102 may be achieved, therefore, even though the doped region 108 is composed of a single doped area 108a, the signal transmission quality is able to be advanced as well.

In particular, note that the conductivity of the guard trace 106 is, for example, higher than the conductivity of the doped region 108, thus, when an electronic signal passes through the routing trace 104, the guard trace 106 with better conductivity, instead of the doped region 108, is preferred and automatically selected by a return signal as the return path thereof. Meanwhile, the doped region 108 disposed between the substrate 102 and the routing trace 104 is served as a shielding structure to reduce crosstalk; in other words, the doped region 108 has a great contribution to shield noise. In addition, by coupling the doped region 108 with the grounded guard trace 106, the noise gathered in the doped region 108 may be further discharged through the guard trace 106 with better conductivity so as to reduce noise diffusion.

In the embodiment of FIG. 1A, the transmission line structure 100 is exemplarily to have one guard trace 106, but the present invention does not limit thereto. In the following a transmission line structure including a plurality of guard traces and the relative disposition between them is depicted.

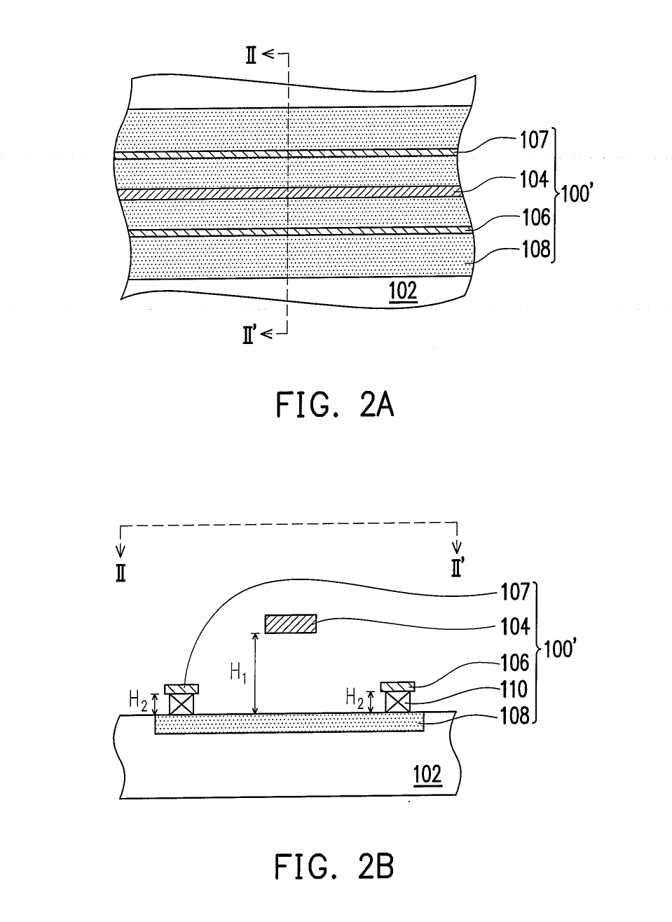

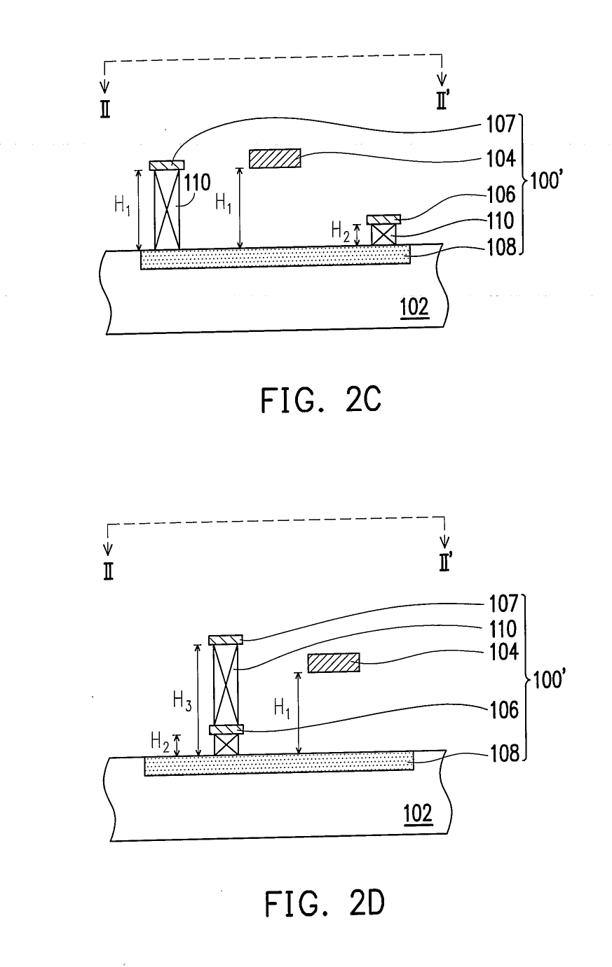

FIG. 2A is a top view diagram of a transmission line structure according to other embodiments of the present invention, FIG. 2B is a cross-sectioned diagram along line II-II′ in FIG. 2A and FIG. 2C is a cross-sectioned diagram along line II-II′ in FIG. 2A according to another embodiment of the present invention. In FIGS. 2A-2C, all the components having the same notations as FIGS. 1A-1E are omitted to describe.

Referring to FIGS. 2A and 2B, the components included by the transmission line structure 100′ are almost the same as the components included by the transmission line structure 100, but except for the routing trace 104, the guard trace 106 and the doped region 108, the transmission line structure 100′ further includes a guard trace 107. The routing trace 104 is disposed between the guard traces 106 and 107. As shown by FIG. 2A, the guard traces 106 and 107 are respectively disposed at both sides of the routing trace 104. The guard traces 106 and 107 are grounded, and via plugs 110 are respectively disposed between the doped region 108 and the guard trace 106, and between the doped region 108 and the guard trace 107, so that the doped region 108 is able to electrically connect the guard traces 106 and 107. The material of the guard trace 107 may be conductive material, for example, metal or poly silicon.

The guard traces 106 and 107 are extended, for example, along a direction parallel to the extension direction of the routing trace 104 and spaced from the routing trace 104. The length of the guard traces 106 and 107 are, for example, equal to the length of the routing trace 104. In the embodiment, the routing trace 104 is located at a height H₁ from the surface of the substrate 102, while the guard traces 106 and 107 are located at a height H₂ from the surface of the substrate 102, wherein the height H₁ is greater than the height H₂, i.e., the guard traces 106 and 107 are located at a same elevation, but different from the elevation the routing trace 104 is located at.

In another embodiment, the disposition relationship between the guard traces 106 and 107 could be that the guard traces 106 and 107 may be located at different elevations from each other. Referring to FIG. 2C, the routing trace 104 and the guard trace 107 are, for example, located at the height H₁ from the surface of the substrate 102, but the guard trace 106 is, for example, located at the height H₂ from the surface of the substrate 102, wherein the height H₁ is greater than the height H₂. In yet another embodiment, the disposition relationship between the routing trace 104, the guard traces 106 and 107 could be that the guard traces 106 and 107 are respectively disposed at both sides of the routing trace 104, but all of the guard traces 106 and 107 and the routing trace 104 are located at the same elevation H₁ (not shown).

FIG. 2D is a cross-sectioned diagram of a transmission line structure according to yet another embodiment of the present invention. In the FIG. 2D, the same components as FIG. 2B are marked by the same notations, which are omitted to describe herein.

Referring to FIG. 2D, the guard traces 106 and 107 are allowed to be disposed at a same side of the routing trace 104. In the embodiment, the guard traces 106 and 107 are located aligning a same vertical plane so as to be adjacent up and down to each other. The routing trace 104 is located at a height H₁ from the surface of the substrate 102, the guard trace 106 is located at a height H₂ from the surface of the substrate 102 and the guard trace 107 is located at a height H₃ from the surface of the substrate 102, wherein the height H₃ is greater than the height H₂ and the height H₁ is between the height H₃ and the height H₂. In yet another embodiment, the disposition relationship between the routing trace 104, the guard traces 106 and 107 could be that the guard traces 106 and 107 are respectively disposed at both sides of the routing trace 104, while the routing trace 104, the guard traces 106 and 107 are respectively located at the heights H₁, H₂ and H₃, wherein the height H₃ is greater than the height H₂ and the height H₁ is between the height H₃ and the height H₂ (not shown).

When the guard traces 106 and 107 are adjacent up and down to each other, the guard traces 106 and 107 would be respectively coupled with the doped region 108 through via plugs 110.

In particular, when the transmission line structure 100′ includes a plurality of guard traces (the guard trace 106 and the guard trace 107), the noise is further prevented from being diffused away in different directions and a good signal return path is provided, which effectively reduces noise interference.

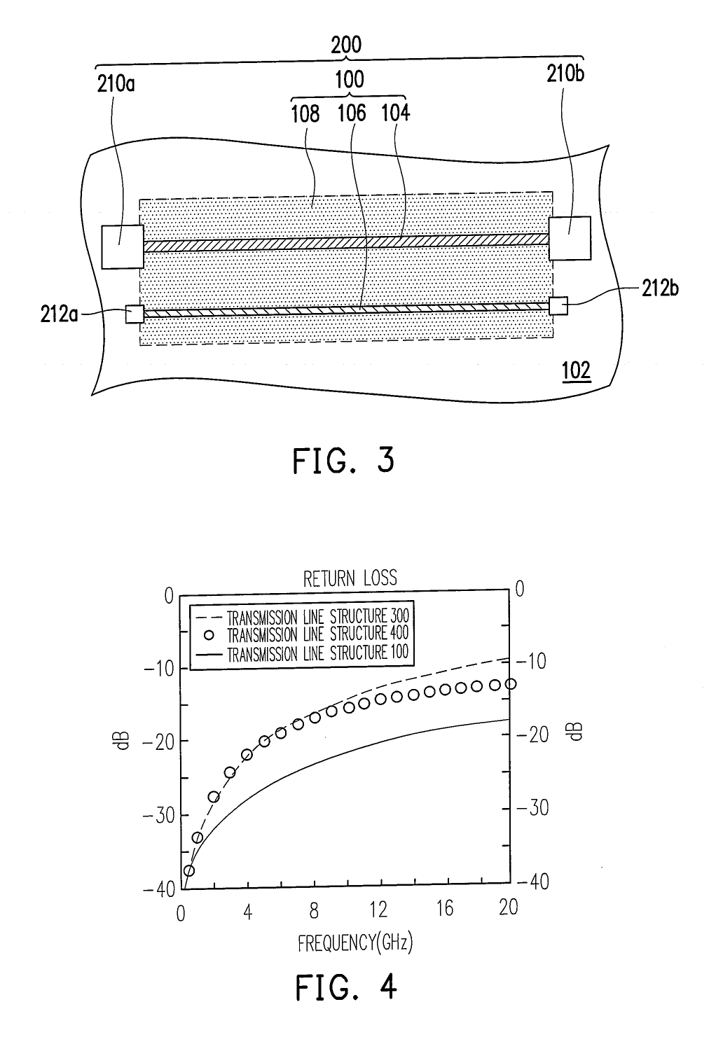

In the following, the application of the above-mentioned transmission line structure 100 in a signal transmission structure is depicted. FIG. 3 is a top view diagram of a signal transmission structure according to an embodiments of the present invention. In FIG. 3, the same components as FIG. 1A are marked by the same notations, which are omitted to describe herein. Besides, for simplification, the dielectric layer is also omitted in FIG. 3.

Referring to FIG. 3, a signal transmission structure 200 includes components 210a and 210b and a transmission line structure 100. The components 210a and 210b are, for example, disposed in a dielectric layer on the substrate 102. The transmission line structure 100 includes a routing trace 104, a guard trace 106 and a doped region 108. The routing trace 104 is disposed in the dielectric layer on the substrate 102 and connected to the components 210a and 210b. The guard trace 106 is, for example, located at an elevation different from the elevation the routing trace 104 is located at. The guard trace 106 is extended, for example, along a direction parallel to the extension direction of the routing trace 104 and disposed at a side of the routing trace 104. In addition, the guard trace 106 is grounded by, for example, respectively electrically connecting the both endpoints thereof to two ground contacts 212a and 212b. The doped region 108 is located in the substrate 102, for example, at the most upper portion of the substrate 102. The projection of at least the partial routing trace 104 would fall within the doped region 108; in the embodiment, the projection of the routing trace 104 completely falls within the doped region 108. In addition, a via plug (not shown) is disposed, for example, between the doped region 108 and the guard trace 106, so that the doped region 108 is electrically coupled with the guard trace 106 to make the doped region 108 grounded through the guard trace 106.

In the embodiment, the components 210a and 210b may respectively be signal contact, circuit component or circuit module. The above-mentioned signal contact is, for example, the one composing a local of a trace layer of a metal interconnect structure. The circuit component may be, for example, active component, passive component or combination of the two above-mentioned ones, wherein the active component is, for example, transmitter, receiver, power amplifier, VCO (voltage control oscillator), or a combination of the above-mentioned components. The circuit module is, for example, memory module, power supply module, passive circuit module, control and logic module, transmitter module or receiver module. The components 210a and 210b may be any two endpoints requiring transmitting electronic signals, and anyone skilled in the art is able to adjust the above-mentioned components to meet the requirement thereof.

As shown by FIG. 3, in the embodiment, the signal transmission structure 200 has, but not limited by the present invention, a guard trace 106. In other embodiments, the signal transmission structure 200 may have a plurality of guard traces 106 and the routing trace 104 is disposed between the guard traces 106 so as to prevent noise diffused away in any direction, which contributed to effectively reduce noise interference. In addition, in the embodiment, the guard trace 106 and the routing trace 104 are exemplarily located at different elevations from each other, however, the guard trace 106 and the routing trace 104 may be located at the same elevation, and the present invention does not limit thereto.

Note that, in the above-mentioned signal transmission structure 200, the guard trace 106 is disposed at a side of the routing trace 104 connecting the components 210a and 210b, the projection of the routing trace 104 falls within the doped region 108 on the surface of the substrate 102, and the doped region 108 is grounded by coupling with the guard trace 106. Therefore, when an IC chip works controlled by a high-frequency clock signal, the guard trace 106 is able to provide a signal return path to reduce crosstalk, the doped region 108 can result in a good effect of shielding noise., and the ground path is able to discharge noise. In this way, the signal transmission structure 200 may more robustly to withstand noise and provide an IC chip with better efficiency.

In the embodiment of FIG. 3, the signal transmission structure 200 exemplarily includes two components and a transmission line structure 100, but the present invention does not limit thereto. In other embodiments, a signal transmission structure may include a plurality of components and a transmission line structure between two adjacent components. Moreover, the transmission line structure may include a plurality of guard traces, which allows to be adjusted by anyone skilled in the art.

FIG. 4 is a graph showing different return loss curves vs. frequencies of clock signal respectively corresponding to the transmission line structure 100 provided by an embodiment of the present invention, and two conventional transmission line structures 300 and 400. In FIG. 4, the conventional transmission line structures are a transmission line structure 300 and a transmission line structure 400, wherein the transmission line structure 300 is a transmission line structure without a guard trace or a doped region disposed, while the transmission line structure 400 has a doped region served as a shielding structure.

Referring to FIG. 4, it can be seen from testing results that in a high-frequence range, since the transmission line structure 400 employs a doped region as a shielding structure, the return loss is improved than that of the transmission line structure 300, but the improvement for the transmission line structure 400 has a limit. Within a range between 0 GHz-20 GHz, the transmission line structure 100 of the present invention has better impedance matching than the transmission line structures 300 and 400. In short, no matter in a low-frequency range or a high-frequency range, the transmission line structure 100 provided by the present invention has a solid positive effect to improve return loss, reduce noise interference and advance signal transmission quality.

In summary, the transmission line structure and the signal transmission structure of the present invention is featured by connecting the doped region to a grounded guard trace. Since the conductivity of the guard trace is higher than the conductivity of the doped region, the doped region is able to be grounded through the guard trace. Under the control by a high-frequency clock signal, the doped region can more effectively prevent an induction coupling between the transmission line structure and the substrate, and the noise gathered in the doped region is easily discharged out of an IC chip. In addition, since the grounded guard trace is extended in a direction parallel to the extension direction of the transmission line structure and spaced from the transmission line structure, a good signal return path is provided, which is helpful to protect signals, effectively reduces crosstalk and avoids the signal transmission quality from noise effecting.

On the other hand, the present invention is able to apply in a radio frequency circuits (RF circuits), the fabricating process of the transmission line structure and the signal transmission structure of the present invention could be integrated in current process without increasing the cost of product or equipment.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A transmission line structure, comprising:
a routing trace, disposed over a substrate;
a doped region, disposed in the substrate, wherein the projection of at least the partial routing trace falls within the doped region; and
a first guard trace, located over the substrate and disposed with a space from the routing trace, wherein the first guard trace is grounded and electrically coupled with the doped region, and the conductivity of the first guard trace is higher than the conductivity of the doped region.

2. The transmission line structure according to claim 1, further comprising at least a via plug disposed between the doped region and the first guard trace to make the doped region electrically coupled with the first guard trace.

3. The transmission line structure according to claim 1, further comprising a second guard trace, and the routing trace is disposed between the first guard trace and the second guard trace.

4. The transmission line structure according to claim 3, wherein the first guard trace and the second guard trace are respectively located at different heights from the substrate.

5. The transmission line structure according to claim 1, wherein the projection of the routing trace completely falls within the doped region.

6. The transmission line structure according to claim 1, wherein the doped region is formed by a plurality of doped areas and each of the doped areas is respectively electrically connected to the first guard trace.

7. The transmission line structure according to claim 1, wherein the substrate is a first conductive type substrate and the doped region is a first conductive type heavily doped region.

8. The transmission line structure according to claim 1, further comprising a well region disposed in the substrate, the doped region is disposed in the well region, the substrate is a first conductive type substrate, the well region is a second conductive type well region and the doped region is a second conductive type heavily doped region.

9. The transmission line structure according to claim 1, wherein the first guard trace is disposed in a direction corresponding to the extension direction of the routing trace.

10. The transmission line structure according to claim 1, wherein the first guard trace and the routing trace are respectively located at different heights from the substrate.

11. A signal transmission structure, comprising:
a plurality of components disposed over a substrate; and
a transmission line structure located between two adjacent components, wherein the transmission line structure comprises:
a routing trace, disposed over the substrate and electrically coupled with the two adjacent components;
a doped region, disposed in the substrate, wherein the projection of at least the partial routing trace falls within the doped region; and
a first guard trace, located over the substrate and disposed with a space from the routing trace, wherein the first guard trace is grounded and electrically coupled with the doped region, and the conductivity of the first guard trace is higher than the conductivity of the doped region.

12. The signal transmission structure according to claim 11, further comprising at least a via plug disposed between the doped region and the first guard trace to make the doped region electrically coupled with the first guard trace.

13. The signal transmission structure according to claim 11, further comprising a second guard trace, and the routing trace is disposed between the first guard trace and the second guard trace.

14. The signal transmission structure according to claim 13, wherein the first guard trace and the second guard trace are respectively located at different heights from the substrate.

15. The signal transmission structure according to claim 11, wherein the projection of the routing trace completely falls within the doped region.

16. The signal transmission structure according to claim 11, wherein the doped region is formed by a plurality of doped areas and each of the doped areas is respectively electrically connected to the first guard trace.

17. The signal transmission structure according to claim 11, wherein the substrate is a first conductive type substrate and the doped region is a first conductive type heavily doped region.

18. The signal transmission structure according to claim 11, further comprising a well region disposed in the substrate, the doped region is disposed in the well region, the substrate is a first conductive type substrate, the well region is a second conductive type well region and the doped region is a second conductive type heavily doped region.

19. The signal transmission structure according to claim 11, wherein the first guard trace is disposed in a direction corresponding to the extension direction of the routing trace.

20. The signal transmission structure according to claim 11, wherein the first guard trace and the routing trace are respectively located at different heights from the substrate.
